(19) United States
(12) Patent Application Publication
(10) Pub. No.: US 2009/0058491 A1
(43) Pub. Date: Mar. 5, 2009

(54) HIGH-TO-LOW LEVEL SHIFTER

(75) Inventors: Tzung-Hung Kang, Hsinchu County (TW); Jong-Woei Chen, Taichung County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/140,329

(22) Filed: Jun. 17, 2008

Related U.S. Application Data
(60) Provisional application No. 60/968,322, filed on Aug. 28, 2007.

(51) Int. Cl. H03L 5/00

(52) U.S. Cl. 327/333

(57) ABSTRACT

A high-to-low level shifter is disclosed, comprising a high voltage unit and a low voltage unit. The high voltage unit receives an input signal from an input node. The high voltage unit outputs a first output signal to an output node when the high voltage unit receives a low-voltage-level input signal. The low voltage unit outputs a second output signal to the output node when the high voltage unit receives a high-voltage-level input signal.

### CROSS REFERENCE TO RELATED APPLICATIONS

This application claims the benefit of U.S. Provisional Application No. 60/968,322, filed Aug. 28, 2007, the disclosure of which is hereby incorporated by reference herein in its entirety.

### BACKGROUND OF THE INVENTION

1. Field of the Invention

The invention relates to a high-to-low level shifter, and in particular relates to a high-speed high-to-low level shifter.

2. Description of the Related Art

A signal may be shifted from a higher voltage level to a lower voltage level because the receiving device may be damaged by the input signal of an overly high voltage level. For example, the input signal is a 5V signal while the receiving device can only withstand a 3.3V signal. A high-to-low level shifter is required to change the voltage level of the input signal, such as shifting it from a 5V signal to a 3.3V signal.

In addition, the required speed of integrated circuits has become faster. Thus, high-speed high-to-low level shifters are desirable to change the voltage levels of signals transmitted between high voltage devices and low voltage devices at a higher speed.

### BRIEF SUMMARY OF THE INVENTION

A detailed description is given in the following embodiments with reference to the accompanying drawings.

An embodiment of a high-to-low level shifter is provided. The high-to-low level shifter comprises a high voltage unit and a low voltage unit. The high voltage unit comprises a first NMOS transistor and a second NMOS transistor. The first NMOS transistor has a gate for receiving an input signal which is at a high logic level or a low logic level. The second NMOS transistor has a gate for receiving an inverted input signal inverse to the input signal, and a drain coupled to an output node. The first and second NMOS transistors are I/O devices. The low voltage unit comprises a feed-forward circuit and a feedback circuit. The feed-forward circuit is arranged to provide an output signal to the output node in response to a voltage level of a drain of the first NMOS transistor. The feedback circuit is arranged to modify the voltage level of the drain of the first NMOS transistor according to the output signal. The feed-forward and feedback circuits are supplied by a first supply voltage lower than a voltage level of the high logic level.

Another embodiment of a high-to-low level shifter is provided. The high-to-low level shifter comprises an input node, an output node, a high voltage unit and a low voltage unit. The high voltage unit is coupled between the input node and the output node, wherein the high voltage unit has an I/O device arranged to pull down a voltage level of the output node to a signal ground when the input node is at a low logic level. The low voltage unit is coupled between the input node and the output node, wherein the low voltage unit has a core device arranged to pull up the voltage level of the output node close to a supply voltage when the input node is at a high logic level, and the supply voltage is lower than a voltage level of the high logic level.

Another embodiment of a high-to-low level shifter is provided. The high-to-low level shifter comprises a high voltage unit and a low voltage unit. The high voltage unit is arranged to receive an input signal from an input node and output a first output signal to an output node. The high voltage unit operates between a first supply voltage and a signal ground, and the input signal varies between the first supply voltage and the signal ground. The low voltage unit, coupled to the high voltage unit, is arranged to output a second output signal to the output node. The low voltage unit operates between a second supply voltage and a signal ground, and the second output signal varies between the second supply voltage and the signal ground. Only one of the first output signal and the second output signal is output to the output node and the first voltage is a higher than the second voltage.

### BRIEF DESCRIPTION OF THE DRAWINGS

The invention can be more fully understood by reading the subsequent detailed description and examples with references made to the accompanying drawings, wherein:

FIG. 1 is a high-to-low level shifter according to an embodiment of the invention;

FIG. 2 is a high-to-low level shifter according to another embodiment of the invention;

FIG. 3 is a high-to-low level shifter according to another embodiment of the invention;

FIG. 4 is a high-to-low level shifter according to another embodiment of the invention;

FIG. 5 is a high-to-low level shifter according to another embodiment of the invention;

FIG. 6 is a high-to-low level shifter according to another embodiment of the invention; and

FIG. 7 is a high-to-low level shifter according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

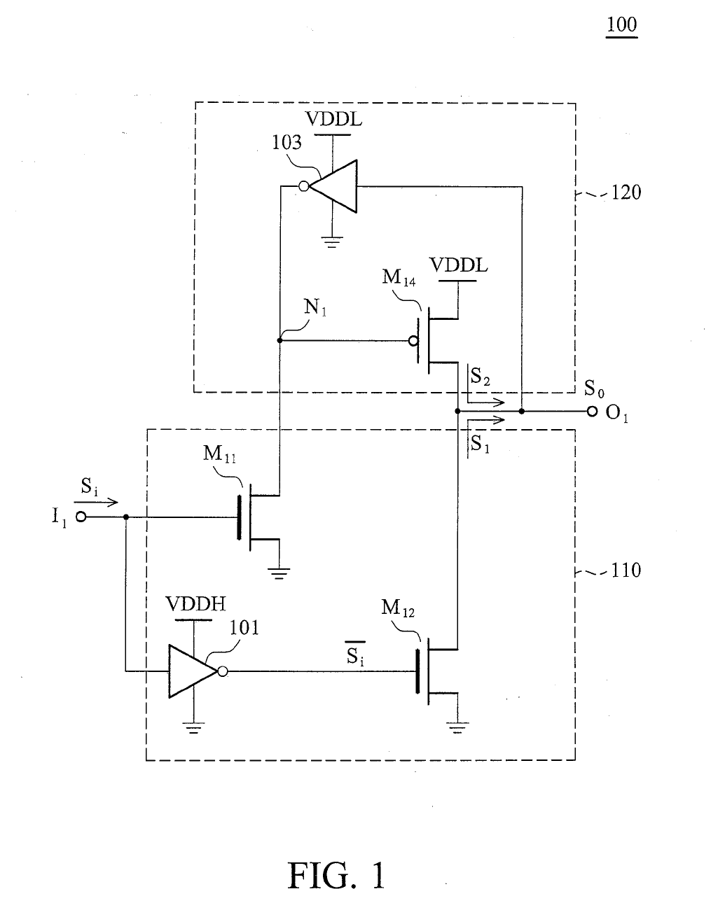

FIG. 1 is a high-to-low level shifter 100 according to an embodiment of the invention. The high-to-low level shifter 100 comprises a high voltage unit 110 and a low voltage unit 120. The high voltage unit 110 comprises NMOS transistors M₁₁ and M₁₂ and an inverter 101. The low voltage unit 120 comprises an inverter 103 and a PMOS transistor M₁₄. The NMOS transistors M₁₁ and M₁₂ and the inverter 101 are I/O (input/output) devices, and the PMOS transistor M₁₄ and the inverter 103 are core devices. That is, the supply voltage VDDH supplied to the high voltage unit 110 is higher than the supply voltage VDDL supplied to the low voltage unit 120. For example, the supply voltage VDDH is 3.3V while the supply voltage VDDL is 1.2V or 0.9V. The NMOS transistors M₁₁ and M₁₂ and the inverter 101 can be operated normally between the supply voltage VDDH and the signal ground. The PMOS transistor M₁₄ and the inverter 103 can be operated normally between the supply voltage VDDL and the signal ground.

As shown in FIG. 1, the high voltage unit 110 receives an input signal Sᵢ from an input node I₁. The voltage level of input signal Sᵢ generally falls in a range from the supply voltage VDDH to the signal ground. The voltage level of output signal S₀, which may be the first output signal S₁ or the second output signal S₂ selectively outputted to the output node O₁ by the high-to-low level shifter 100, falls in a range from the supply voltage VDDL and the signal ground. When the high voltage unit 110 receives the input signal Sᵢ at a low logic level (e.g. representing “0”), of which the voltage level may be equal to the signal ground, the high voltage unit 110 outputs a first output signal S₁ to the output node O₁. When the high voltage unit 110 receives the input signal Sᵢ at a high logic level (e.g. representing “1”), of which the voltage level may be substantially equal to the voltage VDDH, the low voltage unit 120 outputs a second output signal S₂ to the output node O₁. Only one of the first output signal S₁ and the second output signal S₂ is outputted to the output node O₁ as output signal S₀. The first output signal S₁ is at the signal ground, and the second output signal S₂ is at a level substantially equal to the supply voltage VDDL.

When the input signal Sᵢ is at the high logic level, the NMOS transistor M₁₁ is turned on and the NMOS transistor M₁₂ is turned off. Then, the voltage level of a middle node N₁ is pulled down to the signal ground and the PMOS transistor M₁₄ is thus turned on. The voltage level of the output node O₁ is eventually pulled up close to the supply voltage VDDL (about 1.2V or 0.9V).

When the input signal Sᵢ is at the low logic level, the NMOS transistor M₁₁ is turned off and the NMOS transistor M₁₂ is turned on. Then, the voltage level of the output node O₁ is pulled down to the signal ground and the inverter 103 outputs a high voltage level to the middle node N₁. The voltage level of the middle node N₁ is close to the supply voltage VDDL (about 1.2V or 0.9V). Thus, the PMOS transistor M₁₄ is turned off. The voltage level of the output node O₁ is eventually pulled down to the signal ground.

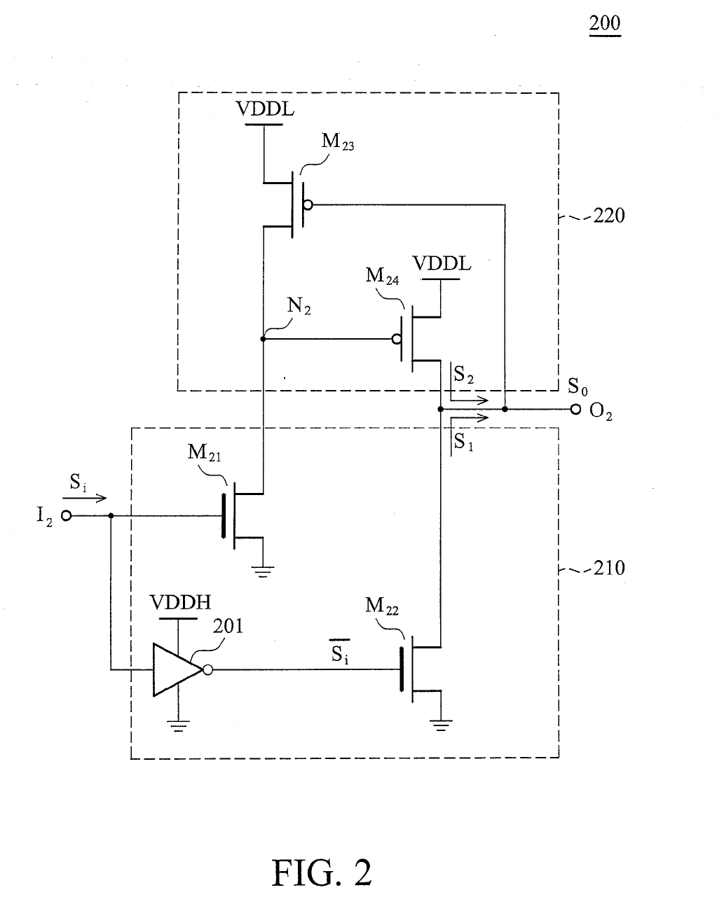

FIG. 2 is a high-to-low level shifter 200 according to another embodiment of the invention. The high-to-low level shifter 200 comprises a high voltage unit 210 and a low voltage unit 220. The high voltage unit 210 comprises NMOS transistors M₂₁ and M₂₂ and an inverter 201. The low voltage unit 220 comprises PMOS transistors M₂₃ and M₂₄. The NMOS transistors M₂₁ and M₂₂ and the inverter 201 are I/O devices, and the PMOS transistors M₂₃ and M₂₄ are core devices. That is, the supply voltage VDDH supplied to the high voltage unit 210 is higher than the supply voltage VDDL supplied to the low voltage unit 220. For example, the supply voltage VDDH is 3.3V while the supply voltage VDDL is 1.2V or 0.9V. The NMOS transistors M₂₁ and M₂₂ and the inverter 201 can be operated normally between the supply voltage VDDH and the signal ground. The PMOS transistors M₂₃ and M₂₄ can be operated normally between the supply voltage VDDL and the signal ground.

Referring to FIG. 2, when the input signal Sᵢ is at the high logic level, the NMOS transistor M₂₁ is turned on and the NMOS transistor M₂₂ is turned off. Then, the voltage level of a middle node N₂ is pulled down to the signal ground and the PMOS transistor M₂₄ is thus turned on. The voltage level of the output node O₂ is pulled up close to the supply voltage VDDL (about 1.2V or 0.9V). The PMOS transistor M₂₃ is turned off since the voltage level of the output node O₂ is close to the supply voltage VDDL.

When the input signal Sᵢ is at the low logic level, the NMOS transistor M₂₁ is turned off and the NMOS transistor M₂₂ is turned on. Then, the voltage level of the output node O₂ is pulled down and the PMOS transistor M₂₃ is turned on, such that the voltage level of the middle node N₂ is pulled up close to the supply voltage VDDL (about 1.2V or 0.9V). Thus, the PMOS transistor M₂₄ is turned off. The voltage level of the output node O₂ is eventually pulled down to the signal ground since the NMOS transistor M₂₂ is turned on and the PMOS transistor M₂₄ is turned off.

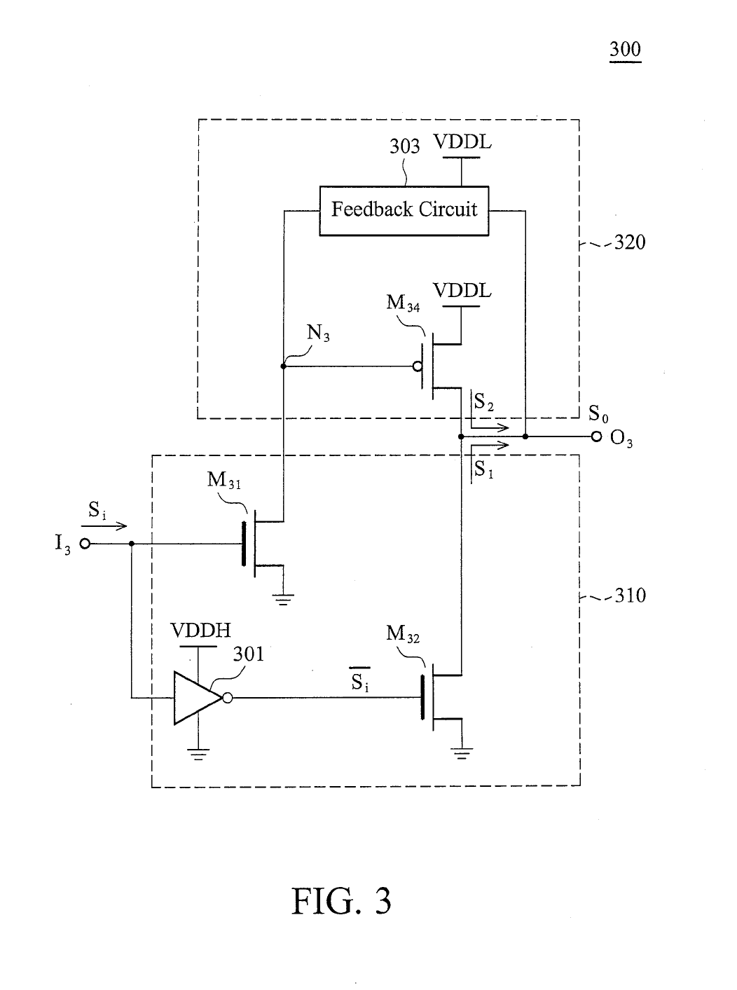

FIG. 3 is a high-to-low level shifter 300 according to another embodiment of the invention. The high-to-low level shifter 300 comprises a high voltage unit 310 and a low voltage unit 320. The high voltage unit 310 comprises NMOS transistors M₃₁ and M₃₂ and an inverter 301. The low voltage unit 320 comprises a feedback circuit 303 and a PMOS transistor M₃₄. The NMOS transistors M₃₁ and M₃₂ and the inverter 301 are I/O devices, the PMOS transistor M₃₄ are core devices, and the feedback circuit 303 comprise core devices. That is, the supply voltage VDDH supplied to the high voltage unit 310 is higher than the supply voltage VDDL supplied to the low voltage unit 320. For example, the supply voltage VDDH is 3.3V and the supply voltage VDDL is 1.2V or 0.9V. The NMOS transistors M₃₁ and M₃₂ and the inverter 301 can be operated normally between the supply voltage VDDH and the signal ground. The PMOS transistor M₃₄ and the feedback circuit 303 can be operated normally between the supply voltage VDDL and the signal ground.

Referring to FIG. 3, when the input signal Sᵢ is at the high logic level, the NMOS transistor M₃₁ is turned on and the NMOS transistor M₃₂ is turned off. Then, the voltage level of a middle node N₃ is pulled down to the signal ground and the PMOS transistor M₃₄ is thus turned on. The voltage level of an output node O₃ is pulled up close to the supply voltage VDDL (about 1.2V or 0.9V) since the PMOS transistor M₃₄ is turned on and the NMOS transistor M₃₂ is turned off. The feedback circuit 303 is a negative feedback circuit, which is arranged to modify the voltage level of the drain of the NMOS transistor M₃₁ according to the output signal S₀, e.g. the voltage level of the output node O₃.

When the input signal Sᵢ is at the low logic level, the NMOS transistor M₃₁ is turned off and the NMOS transistor M₃₂ is turned on. Then, the voltage level of the output node O₃ is pulled down to the signal ground. The feedback circuit 303 then modifies the voltage level of the middle node N₃ to be close to the supply voltage VDDL (about 1.2V or 0.9V).

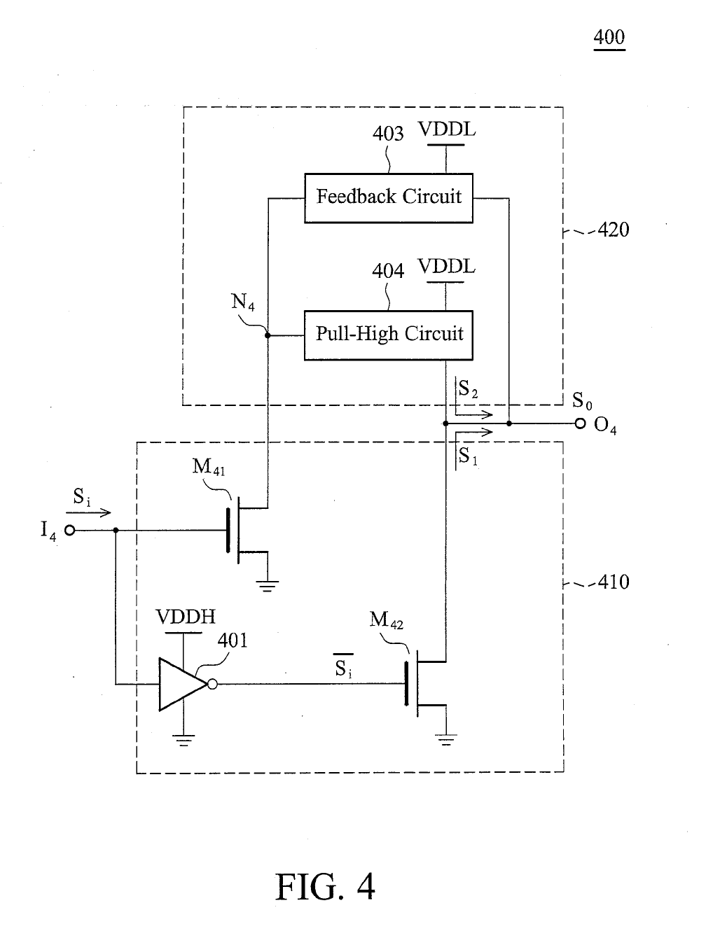

FIG. 4 is a high-to-low level shifter 400 according to another embodiment of the invention. The high-to-low level shifter 400 comprises a high voltage unit 410 and a low voltage unit 420. The high voltage unit 410 comprises NMOS transistors M₄₁ and M₄₂ and an inverter 401. The low voltage unit 420 comprises a feedback circuit 403 and a pull-high circuit 404. The NMOS transistors M₄₁ and M₄₂ and the inverter 401 are I/O devices. The feedback circuit 403 and the pull-high circuit 404 comprise core devices. That is, the supply voltage VDDH supplied to the high voltage unit 410 is higher than the supply voltage VDDL supplied to the low voltage unit 420. For example, the supply voltage VDDH is 3.3V and the supply voltage VDDL is 1.2V or 0.9V. The NMOS transistors M₄₁ and M₄₂ and the inverter 401 can be operated normally between the supply voltage VDDH and the signal ground. The feedback circuit 403 and the pull-high circuit 404 can be operated normally between the supply voltage VDDL and the signal ground.

Referring to FIG. 4, when the input signal Sᵢ is at the high logic level, the NMOS transistor M₄₁ is turned on and the NMOS transistor M₄₂ is turned off. Then, the voltage level of a middle node N₄ is pulled down to the signal ground. According to the voltage level of the middle node N₄, e.g. the signal ground, the pull-high circuit 404 pulls up the voltage level of an output node O₄ close to the supply voltage VDDL (about 1.2V or 0.9V). Moreover, the feedback circuit 403 is a negative feedback circuit, which is arranged to modify the voltage level of the middle node N₄ according to the output signal S₀, e.g. the voltage level of an output node O₄. Therefore, by these two paths, one is provided through the pull-high circuit 404 and the other is provided through the feedback circuit 403, the voltage levels of the middle node N₄ and the output node O₄ respond to each other rapidly.

When the input signal Sᵢ is at the low logic level, the NMOS transistor M₄₁ is turned off and the NMOS transistor M₄₂ is turned on. Then, the voltage level of the output node O₄ is pulled down to the signal ground since the NMOS transistor M₄₂ is turned on. The feedback circuit 403 then modifies the voltage level of the middle node N₄ to be at the supply voltage VDDL. The pull-high circuit 404 does not pull up the voltage level of the output node O₄ when the voltage level of the middle node N₄ is already at the supply voltage VDDL.

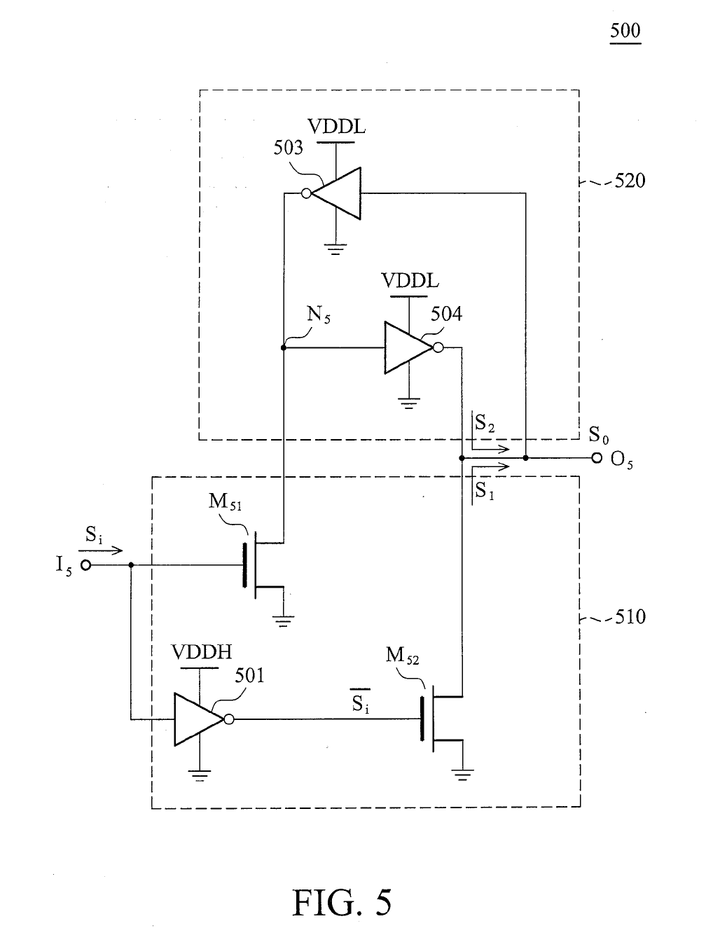

FIG. 5 is a high-to-low level shifter 500 according to another embodiment of the invention. The high-to-low level shifter 500 comprises a high voltage unit 510 and a low voltage unit 520. The high voltage unit 510 comprises NMOS transistors M₅₁ and M₅₂ and an inverter 501. The low voltage unit 520 comprises inverters 503 and 504. The NMOS transistors M₅₁ and M₅₂ and the inverter 501 are I/O devices. The inverters 503 and 504 are core devices. That is, the supply voltage VDDH supplied to the high voltage unit 510 is higher than the supply voltage VDDL supplied to the low voltage unit 520. For example, the supply voltage VDDH is 3.3V and the supply voltage VDDL is 1.2V or 0.9V. The NMOS transistors M₅₁ and M₅₂ and the inverter 501 can be operated normally between the supply voltage VDDH and the signal ground. The inverters 503 and 504 can be operated normally between the supply voltage VDDL and the signal ground.

When the input signal Sᵢ is at the high logic level, the NMOS transistor M₅₁ is turned on and the NMOS transistor M₅₂ is turned off. Then, the voltage level of a middle node N₅ is pulled down to the signal ground. The voltage level of an output node O₅ is pulled up close to the supply voltage VDDL (about 1.2V or 0.9V) by inverting the voltage level of the middle node N₅ through the inverter 504. Sequentially, the inverter 503 keeps the voltage level of the middle node N₅ at the signal ground according to the voltage level of the output node O₅, e.g. the supply voltage VDDL (about 1.2V or 0.9V).

When the input signal Sᵢ is at the low logic level, the NMOS transistor M₅₁ is turned off and the NMOS transistor M₅₂ is turned on. Then, the voltage level of the output node O₅ is pulled down and the inverter 503 thus makes the voltage level of the middle node N₅ be close to the supply voltage VDDL (about 1.2V or 0.9V). The inverter 504 outputs a low voltage level (e.g. the signal S₂) to the output node O₅ according to the voltage level of the middle node N₅.

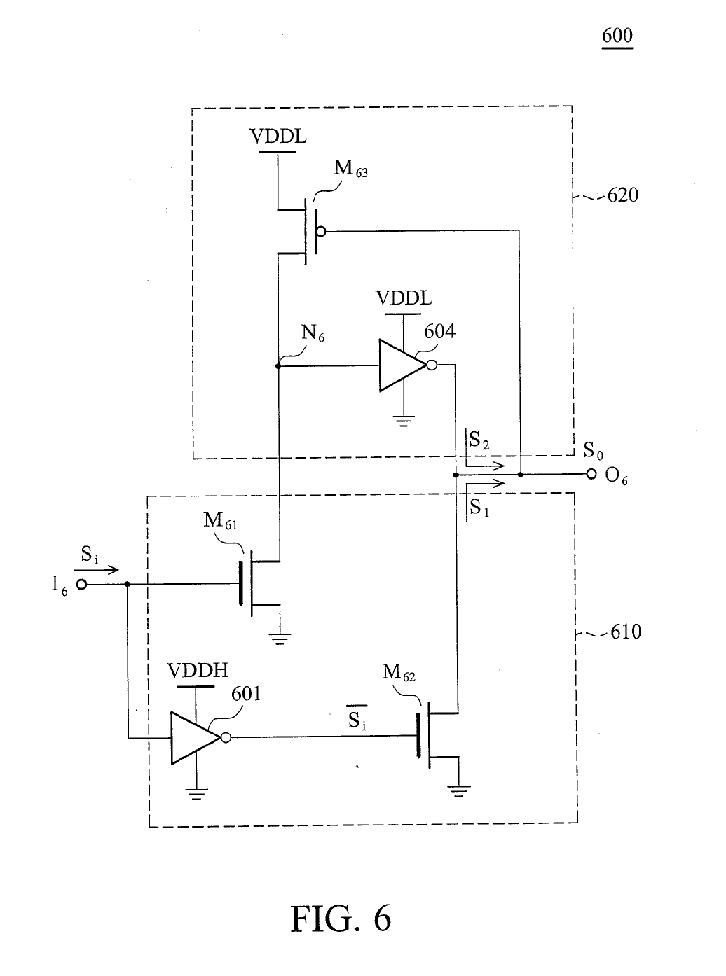

FIG. 6 is a high-to-low level shifter 600 according to another embodiment of the invention. The high-to-low level shifter 600 comprises a high voltage unit 610 and a low voltage unit 620. The high voltage unit 610 comprises NMOS transistors M₆₁ and M₆₂ and an inverter 601. The low voltage unit 620 comprises an inverter 604 and a PMOS transistor M₆₃. The NMOS transistors M₆₁ and M₆₂ and the inverter 601 are I/O devices. The PMOS transistors M₆₃ and the inverter 604 are core devices. That is, the supply voltage VDDH supplied to the high voltage unit 610 is higher than the supply voltage VDDL supplied to the low voltage unit 620. For example, the supply voltage VDDH is 3.3V and the supply voltage VDDL is 1.2V or 0.9V. The NMOS transistors M₆₁ and M₆₂ and the inverter 601 can be operated normally between the supply voltage VDDH and the signal ground. The PMOS transistors M₆₃ and the inverter 604 can be operated normally between the supply voltage VDDL and the signal ground.

Referring to FIG. 6, when the input signal Sᵢ is at the high logic level, the NMOS transistor M₆₁ is turned on and the NMOS transistor M₆₂ is turned off. Then, the voltage level of an input node N₆ is pulled down to the signal ground. The voltage level of an output node O₆ is pulled up close to the supply voltage VDDL (about 1.2V or 0.9V) by inverting the voltage level of the middle node N₆ through the inverter 604. The PMOS transistor M₆₃ is turned off since the voltage level of the output node O₆ is close to the supply voltage VDDL.

When the input signal Sᵢ is at the low logic level, the NMOS transistor M₆₁ is turned off and the NMOS transistor M₆₂ is turned on. Then, the voltage level of the output node O₆ is pulled down and the PMOS transistor M₆₃ is thus turned on. The voltage level of a middle node N₆ is pulled up close to the supply voltage VDDL (about 1.2V or 0.9V). The inverter 604 outputs a low voltage level (e.g. the signal S₂) to the output node O₆ according to the voltage level of the middle node N₆.

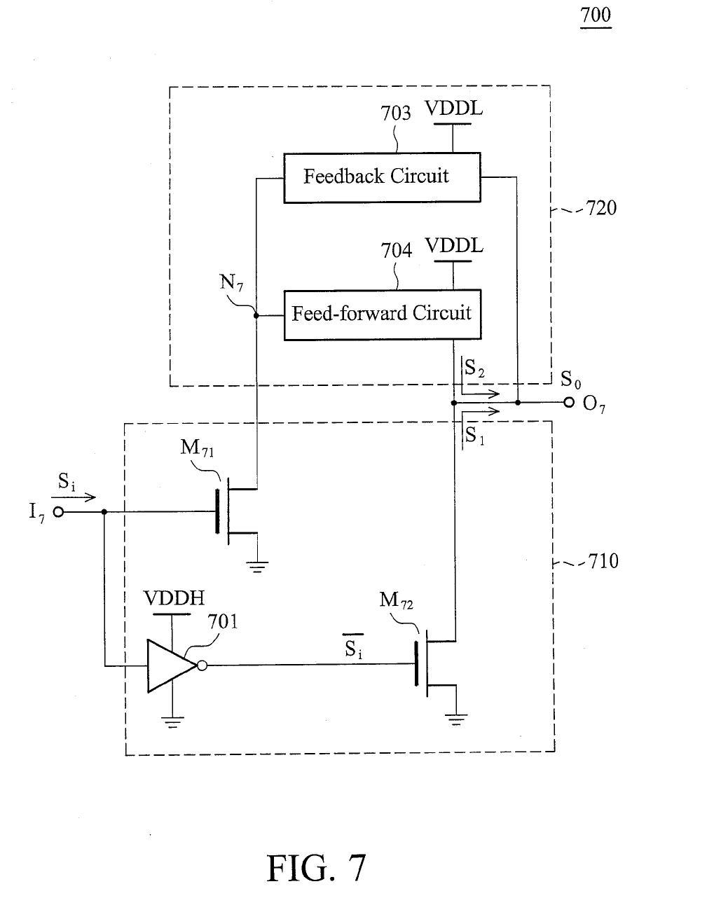

FIG. 7 is a high-to-low level shifter 700 according to another embodiment of the invention. The high-to-low level shifter 700 comprises a high voltage unit 710 and a low voltage unit 720. The high voltage unit 710 comprises NMOS transistors M₇₁ and M₇₂ and an inverter 701. The low voltage unit 720 comprises a feedback circuit 703 and a feed-forward circuit 704. The NMOS transistors M₇₁ and M₇₂ and the inverter 701 are I/O devices. The feedback circuit 703 and the feed-forward circuit 704 comprise core devices. That is, the supply voltage VDDH supplied to the high voltage unit 710 is higher than the supply voltage VDDL supplied to the low voltage unit 720. For example, the supply voltage VDDH is 3.3V and the supply voltage VDDL is 1.2V or 0.9V. The NMOS transistors M₇₁ and M₇₂ and the inverter 701 can be operated normally between the supply voltage VDDH and the signal ground. The feedback circuit 703 and the feed-forward circuit 704 can be operated normally between the supply voltage VDDL and the signal ground.

Referring to FIG. 7, when the input signal Sᵢ is at the high logic level, the NMOS transistor M₇₁ is turned on and the NMOS transistor M₇₂ is turned off. Then, the voltage level of a middle node N₇ is pulled down to the signal ground. The feed-forward circuit 704 is arranged to provide an output signal So to the output node O₇ in response to a voltage level of a drain of the NMOS transistor M₇₁. The feedback circuit 703 is arranged to modify the voltage level of the drain of the NMOS transistor M₇₁ according to the output signal S₀, e.g. the voltage level of the output node O₇.

When the input signal Sᵢ is at the low logic level, the NMOS transistor M₇₁ is turned off and the NMOS transistor M₇₂ is turned on. Then, the voltage level of the output node O₇ is pulled down to the signal ground. The feedback circuit 703 then modifies the voltage level of middle node N₇ to be close to the supply voltage VDDL (about 1.2V or 0.9V). Sequentially, the feed-forward circuit 704 provides the output signal S₀ on the output node O₇ in response to the voltage level of the output node N₇.

In summary, according to the above embodiments, the high voltage unit utilizes I/O devices and the low voltage unit utilizes core devices for high-speed high-to-low shifter applications. Specifically, the I/O devices which can be operated by a higher supply voltage (VDDH), and the core devices which can be operated by a lower supply voltage (VDDL). In some embodiments, the I/O devices and the core devices may have different threshold voltages (e.g. the former is greater than the later), or have different gate oxide thicknesses, or the like. Using the embodiment as illustrated in FIG. 2 as an example, since the NMOS transistor M₂₁ or M₂₂ is I/O device, the NMOS transistor M₂₁ or M₂₂ can operate at a high speed due to its high Vgs while being turned on; and, the PMOS transistor M₂₃ and M₂₄ can rapidly operate under the low supply voltage (VDDL) since they are implemented by core devices.

While the invention has been described by way of example and in terms of preferred embodiment, it is to be understood that the invention is not limited to thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A high-to-low level shifter, comprising:
a high voltage unit, comprising:
a first NMOS transistor having a gate for receiving an input signal, wherein the input signal is at a high logic level or a low logic level; and
a second NMOS transistor having a gate for receiving an inverted input signal inverse to the input signal, and a drain coupled to an output node, wherein the first and second NMOS transistors are I/O devices; and
a low voltage unit, comprising
a feed-forward circuit, for providing an output signal to the output node in response to a voltage level of a drain of the first NMOS transistor; and
a feedback circuit, for modifying the voltage level of the drain of the first NMOS transistor according to the output signal, wherein the feed-forward and feedback circuits are supplied by a first supply voltage lower than a voltage level of the high logic level.

2. The high-to-low level shifter as claimed in claim 1, wherein the feed-forward and feedback circuits comprise core devices.

3. The high-to-low level shifter as claimed in claim 1, wherein the feedback circuit comprises an inverter coupled between the drain of the first NMOS transistor and the output node.

4. The high-to-low level shifter as claimed in claim 1, wherein the feedback circuit comprises a PMOS transistor having a source coupled to the first supply voltage, a gate coupled to the output node, and a drain coupled to the drain of the first NMOS transistor.

5. The high-to-low level shifter as claimed in claim 1, wherein the feed-forward circuit comprises an inverter coupled between the drain of the first NMOS transistor) and the output node.

6. The high-to-low level shifter as claimed in claim 1, wherein the feed-forward circuit comprises a PMOS transistor having a source coupled to the first supply voltage, a gate coupled to the drain of the first NMOS transistor, and a drain coupled to the output node.

7. The high-to-low level shifter as claimed in claim 1, wherein the feed-forward circuit is a pull-high circuit.

8. The high-to-low level shifter as claimed in claim 1, wherein the high voltage unit further comprises an inverter for converting the input signal into an inverted input signal, and the inverter is supplied by a second supply voltage higher than the first supply voltage.

9. A high-to-low level shifter, comprising:
an input node;
an output node;
a high voltage unit coupled between the input node and the output node, wherein the high voltage unit has an I/O device arranged to pull down a voltage level of the output node to a signal ground when the input node is at a low logic level; and
a low voltage unit coupled between the input node and the output node, wherein the low voltage unit has a core device arranged to pull up the voltage level of the output node close to a supply voltage when the input node is at a high logic level, and the supply voltage is lower than a voltage level of the high logic level.

10. A high-to-low level shifter, comprising:
a high voltage unit for receiving an input signal from an input node and outputting a first output signal to an output node, wherein the high voltage unit operates between a first supply voltage and a signal ground and the input signal varies between the first supply voltage and the signal ground; and
a low voltage unit, coupled to the high voltage unit, for outputting a second output signal to the output node, wherein the low voltage unit operates between a second supply voltage and a signal ground and the second output signal varies between the second supply voltage and the signal ground,
wherein only one of the first output signal and the second output signal is output to the output node, and the first supply voltage is a higher than the second supply voltage.

11. The high-to-low level shifter as claimed in claim 10, wherein when the high voltage unit receives the input signal at a high logic level, the second output signal is output to the output node, and when the high voltage unit receives the input signal at a low logic level, the first output signal is output to the output node.

12. The high-to-low level shifter as claimed in claim 10, wherein the first output signal is approximately at the signal ground and the second output signal is approximately at the second supply voltage

13. The high-to-low level shifter as claimed in claim 10, wherein the high voltage unit comprises:
a first NMOS transistor comprising a gate to receive the input signal, a source coupled to the signal ground and a drain coupled to a middle node of the low voltage unit;
a first inverter for inverting the input signal and outputting a first inverted signal; and
a second NMOS transistor comprising a gate to receive the first inverted signal, a source coupled to the signal ground and a drain coupled to the output node to output the first output signal.

14. The high-to-low level shifter as claimed in claim 13, wherein when the high voltage unit receives the input signal at a low logic level, the second NMOS transistor is turned on to output the first output signal.

15. The high-to-low level shifter as claimed in claim 13, wherein the low voltage unit comprises:
a first PMOS transistor comprising a gate coupled to the middle node, a source coupled to the second supply voltage and a drain coupled to the output node to output the second output signal; and
a second PMOS transistor comprising a gate coupled to the output node, a source coupled to the second supply voltage and a drain coupled to the middle node.

16. The high-to-low level shifter as claimed in claim 15, wherein when the middle node is at the signal ground, the first PMOS transistor is turned on to output the second output signal.

17. The high-to-low level shifter as claimed in claim 13, wherein the low voltage unit comprises:
a PMOS transistor comprising a gate coupled to the middle node, a source coupled to the second supply voltage and a drain coupled to the output node to output the second output signal; and
a second inverter for outputting a signal at the middle node of which a logic level is inverse to that of a signal at the output node.

18. The high-to-low level shifter as claimed in claim 13, wherein the low voltage unit comprises:
a PMOS transistor comprising a gate coupled to the middle node, a source coupled to the second supply voltage and a drain coupled to the output node to output the second output signal; and
a feedback circuit for modifying a signal at the middle node according to a signal at the output node.

19. The high-to-low level shifter as claimed in claim 13, wherein the low voltage unit comprises:
a pull-high circuit pulling up a voltage level of the output node when the middle node is close to the signal ground; and
a feedback circuit for modifying a signal at the middle node according to the voltage level of the output node.

20. The high-to-low level shifter as claimed in claim 13, wherein the low voltage unit comprises:
a second inverter for outputting a signal at the middle node of which a logic level is inverse to that of a signal at the output node; and
a third inverter for modifying the signal at the middle node according to the signal at the output node.

21. The high-to-low level shifter as claimed in claim 13, wherein the low voltage unit comprises:
a second inverter for outputting a signal at the middle node of which a logic level is inverse to that of a signal at the output node; and
a PMOS transistor comprising a gate coupled to the output node, a source coupled to the second supply voltage and a drain coupled to the middle node.

22. The high-to-low level shifter as claimed in claim 13, wherein the low voltage unit comprises:
a feed-forward circuit for providing the second output signal to the output node in response to a signal at the middle node; and
a feedback circuit for modifying the signal at the middle node according to a signal at the output node.
